(19) United States
(12) Patent Application Publication
(10) Pub. No.: US 2005/0016466 A1
(43) Pub. Date: Jan. 27, 2005

(54) Susceptor with raised tabs for semiconductor wafer processing

(75) Inventors: Lance Scudder, Santa Clara, CA (US); Michael E. Thompson, San Jose, CA (US); Robert Trujillo, Santa Clara, CA (US)

Correspondence Address: PATENT COUNSEL;APPLIED MATERIALS, INC., Legal Affairs Department, P.O. BOX 450A, Santa Clara, CA, 95052, US

(73) Assignee: Applied Materials, Inc.

(21) Appl. No.: 10/626,174

(22) Filed: Jul. 23, 2003

(51) Int. Cl. H01L 21/31; C23C 16/00; H01L 21/469

(52) U.S. Cl. 118/728; 118/719

(57) ABSTRACT

Described is a susceptor with a wafer pocket, to contain a wafer during a wafer processing procedure, and a plurality of raised tabs along the outer perimeter of the wafer pocket that are configured to maintain the wafer in the wafer pocket during wafer processing. The tabs have a tab height that is independent of the pocket depth.

### FIELD

The present invention relates generally to the field of semiconductor technology and, more specifically, to a susceptor in a semiconductor wafer processing apparatus.

### BACKGROUND

Deposition of a film on the surface of a semiconductor wafer is a common step in semiconductor processing. The process of depositing layers on a semiconductor wafer (or substrate) usually involves placing the substrate within a processing chamber and holding the wafer within a stream of a reactant gas flowing across the surface of a wafer while applying heat to drive the chemical reaction of the gas and the wafer surface. A thin film is consequently formed on the wafer surface. Inside the processing chamber, the wafer is held within a susceptor, as illustrated in FIGS. 1A-1B. FIG. 1A is a cross-sectional side view of a wafer 106 inside a susceptor 100. FIG. 1B is a top view of the wafer 106 inside the susceptor 100. Referring to FIGS. 1A-1B, the susceptor 110 includes a cylindrical pocket 104 (“pocket”) that is defined by at least one annular, or planar, bottom surface 108 and a cylindrical sidewall 110. The pocket 104 is to restrain movement of the wafer 106 within the susceptor 110.

A common problem in conventional wafer processing is a phenomenon known as “wafer-out-of-pocket”, illustrated in FIGS. 2A-2B. FIG. 2A is a cross-sectional side view and FIG. 2B is a top view of the wafer 106 outside of the pocket 104. In some instances during the wafer processing, the wafer 106 may become stressed by processing events (e.g., rapid temperature changes) causing the wafer 106 to become agitated and move around within the pocket 104. If the movement is excessive, the wafer 106 may even become dislodged from the pocket 104, causing the wafer to be out of alignment with a reactant gas flow stream, leading to a deformed thin film deposition over the wafer 106. Wafers with deformed thin films caused by wafer-out-of-pocket are discarded, thus adversely affecting process efficiency and resulting in higher wafer processing costs.

One conventional approach to reducing movement of the wafer inside the pocket has been to introduce tabs 302, as shown in FIGS. 3A-3B. FIG. 3A is a cross-sectional side view and FIG. 3B is an perspective view of the wafer 106 inside the susceptor 100 having tabs 302 to capture the edge 304 of the wafer 106 during some wafer processing events that may cause wafer-out-of-pocket. The tabs 302 and the sidewall 110 of the pocket 104 are designed to the same height (h_{tab/pocket}). However, for the tabs 302 to be effective at preventing wafer-out-of-pocket, they must have a height (h_{tab/pocket}) that is considerably more than the height of the wafer (h_{wafer}). Unfortunately, since the tab height (h_{tab/pocket}) is constrained to be as tall as the sidewall 110, the pocket depth must also extend to the same considerable height (h_{tab/pocket}), thus resulting in an excessively deep pocket 104. During the formation of a thin film 308 on the wafer, the considerable height of the sidewall 110 causes the gas flow (indicated by arrows) to flow unevenly near the wafer edge 304, thus causing the thin-film material 308 to form very thinly on top of the wafer surface near the edge 304 of the wafer 106. These “thin edges” 310 cause problems during subsequent processing, testing, or operation of the wafer 106. For example, because of the thin etch 310, additional thin film layers that are formed above the first thin-film 308 also include thin edges. Thus, devices near the edge 304 of the wafer 106 are subsequently formed improperly.

### SUMMARY

A susceptor with raised tabs is described. According to one embodiment of the invention, a susceptor includes raised tabs to maintain a wafer inside the wafer pocket of the susceptor. The tabs have a tab height that is independent of the pocket depth, hence the pocket sidewall can be low, allowing for a uniform deposition of a thin film on the wafer, while the tabs can be raised above the pocket to capture and contain a wafer inside the wafer pocket during stressful processing conditions that would otherwise cause the wafer to leap above the pocket sidewall and out of the wafer pocket. Additionally, the raised tabs extend into the pocket towards the center of the pocket to maintain the wafer separated from the pocket sidewall to keep the wafer away from the thermal influence of the sidewall during processing. Furthermore, the tabs are aerodynamically shaped to minimize interference with a laminar gas flow during processing. More specifically, the tabs include smooth surfaces, rounded edges, and smooth transitions into the sidewall and bottom surface of the pocket.

Other features, according to other embodiments of the present invention, will be apparent from the accompanying drawings and from the detailed description that follows.

### BRIEF DESCRIPTION OF THE DRAWINGS

Embodiments of the present invention are illustrated by way of example and should not be limited by the figures of the accompanying drawings in which like references indicate similar elements and in which:

FIGS. 1A-1B illustrate a conventional susceptor and wafer;

FIGS. 2A-2B illustrate the conventional wafer out of the wafer pocket;

FIGS. 3A-3B illustrate a conventional tabbed susceptor;

FIG. 4 illustrates a multiple-chamber integrated process system for wafer processing;

FIG. 5 illustrates a cross-sectional view of an exemplary semiconductor processing chamber with a susceptor according to one embodiment of the invention;

FIGS. 6A-6F illustrate a semiconductor wafer susceptor with raised tabs according to one embodiment of the invention;

FIG. 7 is a graph of thickness uniformity for a thin film formed on the susceptor with raised tabs;

FIG. 8 is a graph of thickness uniformity for a thin film formed on the susceptor without raised tabs;

FIGS. 9A-9D illustrate a susceptor having removable raised tabs;

FIGS. 10A-10D illustrate a susceptor with a tab holder that holds tabs to be lifted up through the susceptor into a raised position from underneath the susceptor; and

FIGS. 11A-11B illustrate a method, according to one embodiment of the invention, showing tabs being lifted into a raised position.

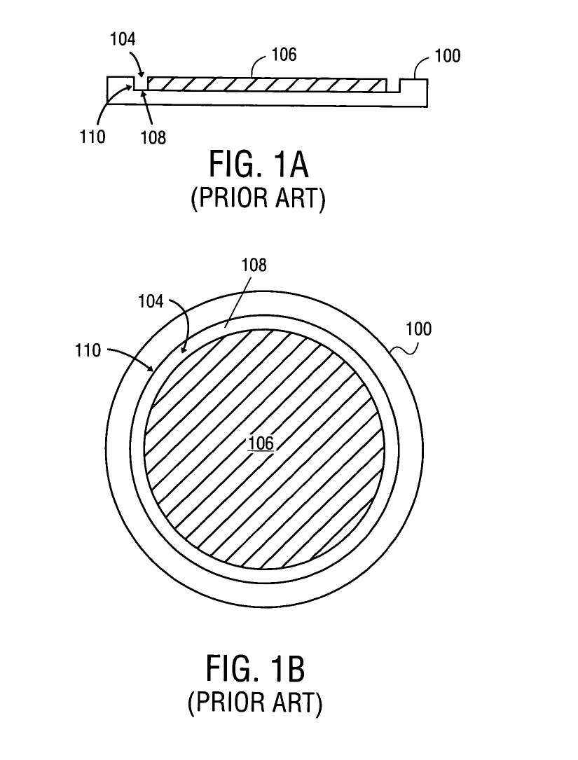

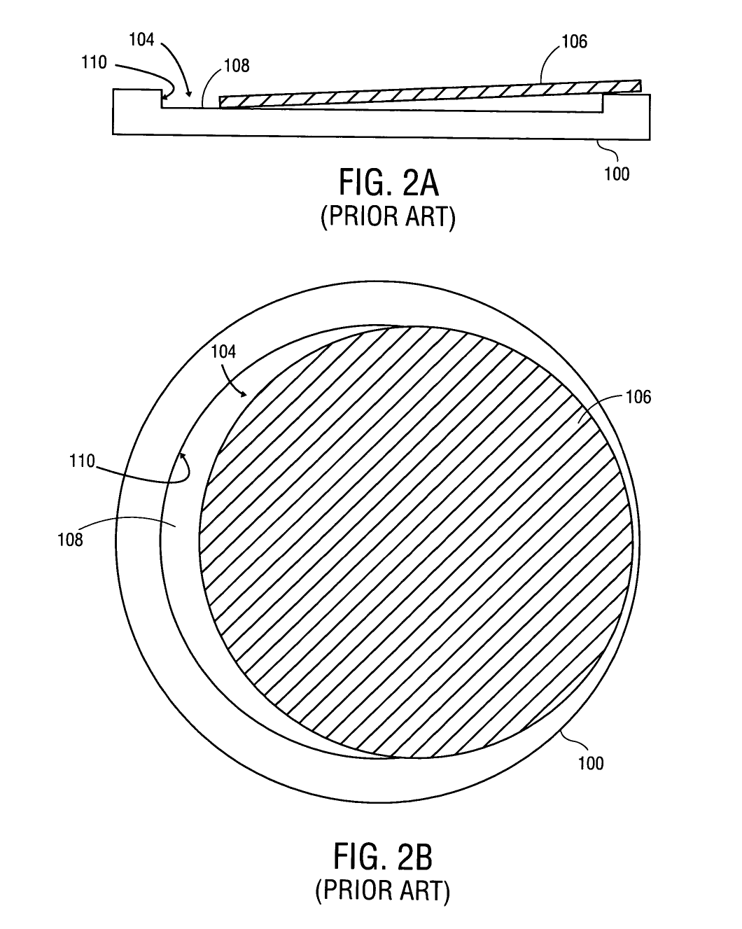

### DETAILED DESCRIPTION

Described herein is a susceptor with raised tabs. In the following description numerous specific details are set forth. One of ordinary skill in the art, however, will appreciate that these specific details are not necessary to practice embodiments of the invention. While certain exemplary embodiments of the invention are described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art. In other instances well known semiconductor fabrication processes, techniques, materials, equipment, etc., have not been set forth in particular detail in order to not unnecessarily obscure embodiments of the present invention.

A susceptor with raised tabs is described. According to one embodiment of the invention a susceptor includes raised tabs to maintain a wafer inside the wafer pocket of the susceptor. The tabs have a tab height that is independent of the pocket depth, hence the pocket depth can be low, allowing for thin film uniformity, and the tabs can be tall, preventing the wafer from moving beyond the confines of the pocket during stressful wafer conditions, or in other words, to confine the wafer inside the wafer pocket. Additionally, the raised tabs extend into the pocket to center the wafer within the pocket and the tabs have a smooth aerodynamic shape that allows gas to flow around the raised tab without detrimentally affecting the uniformity of a thin layer. Consequently, thin layers can be uniformly formed on a wafer during wafer processing and the undesirable phenomenon of wafer-out-of-pocket is eliminated.

Definitions

In embodiments of the invention described herein, a susceptor tab is described as being “raised”, or more specifically as a “raised tab”. In some embodiments of the invention, the height of the tab (“tab height”) is described as being fixed in a position that is taller than the depth of a susceptor pocket (“pocket depth”). In other embodiments of the invention, however, the susceptor may utilize a tab that is adjustable, and not necessarily always in a fixed raised position. Therefore, the term “raised tabs” may be utilized herein to mean tabs that are either raised, or capable of being raised, above the height of the susceptor pocket.

Description of Susceptor and Wafer Processing System

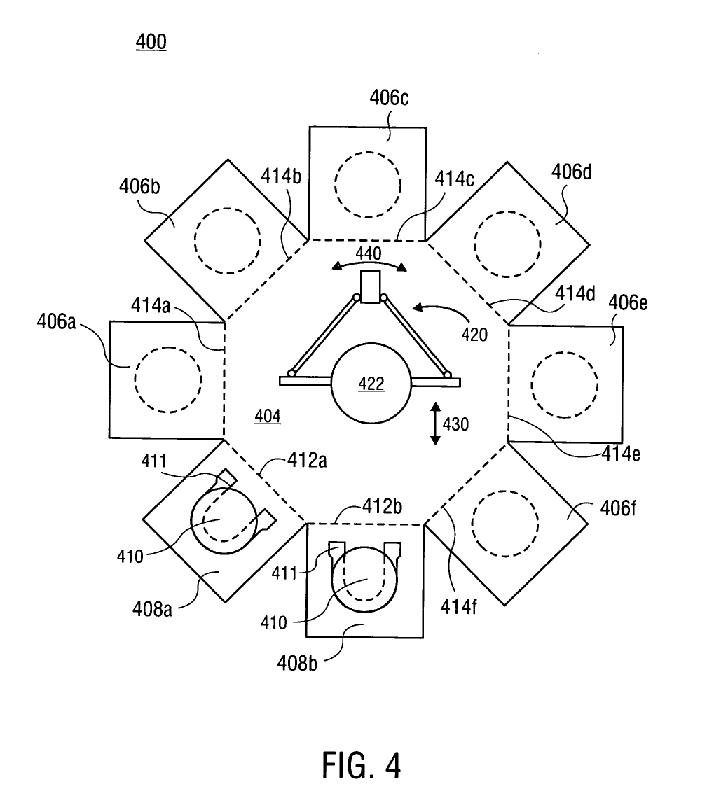

FIG. 4 illustrates a multiple-chamber integrated process system 400 including an enclosed main frame having sidewalls that define an enclosed vacuum transfer chamber 404. A number of individual processing chambers 406a-f are mounted one each on an associated sidewall of the transfer chamber 404. Two load lock cassette elevators 408a and 408b are adapted for vertically stacking a multiplicity of cassettes that hold wafers 410 horizontally. The load lock cassette elevators 408a and 408b selectively position each cassette directly opposite and aligned with a transfer chamber entrance slit or opening 412a and 412b, respectively. Each cassette holds multiple wafers. Wafers 410 are held within the cassette by a set of support structures 411 having a diameter that is slightly larger than the diameter of the wafers being housed.

Processing chambers 406a-f and the associated main frame sidewalls also have communicating slits 414a-f, respectively, which are similar to the load lock entrance slits 412a and 412b. A robotic wafer transfer system 420 is mounted within transfer chamber 404 for transferring wafers 410 between load locks 408a and 408b and the individual processing chambers 406a-f. Robot assembly 420 includes a driver (not shown) that imparts both rotational and reciprocating movement to blade 422 for affecting the desired cassette-to-chamber, chamber-to-chamber and chamber-to-cassette wafer transfer. The reciprocating movement (straight line extension and retraction) is indicated by arrow 430, while the pivotal or rotational movement is indicated by arrow 440.

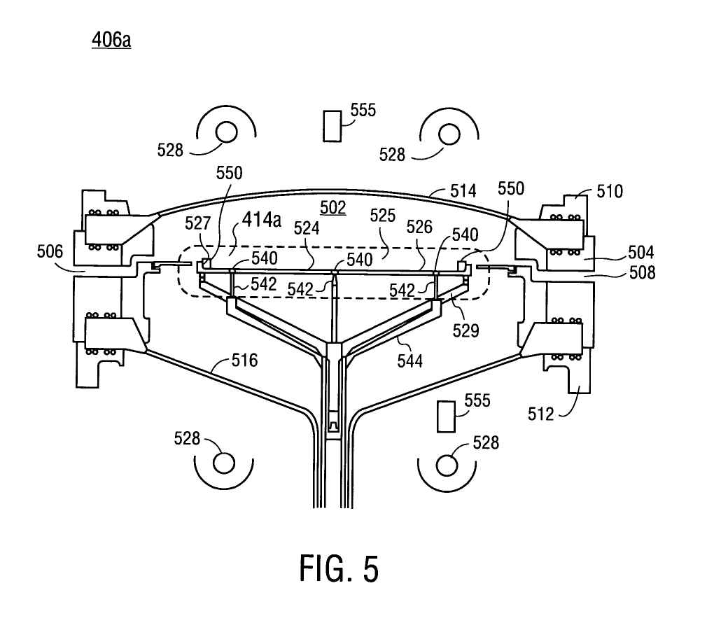

FIG. 5 illustrates a cross-sectional view of an exemplary semiconductor processing chamber 406a, as depicted in FIG. 4. Processing chamber 406a includes an inner chamber 502 for facilitating the flow of a process gas over the surface of a wafer. The housing includes a base plate 504 having a gas inlet port 506 and a gas exhaust port 508. An upper clamp ring 510 and a lower clamp ring 512 act to hold a quartz cover member 514 and a quartz lower member 516 in place, respectively. Process gas is injected into chamber 502 through gas inlet port 506, which is connected to a gas source. Residual process gas and various waste products are continuously removed from the interior of chamber 502 through exhaust port 508.

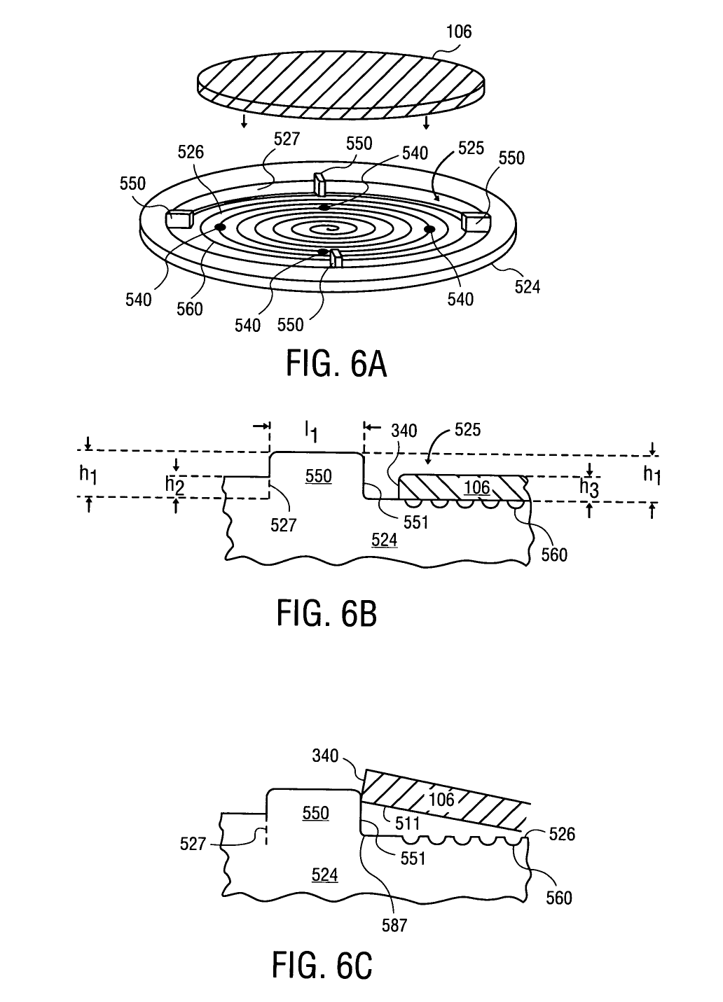

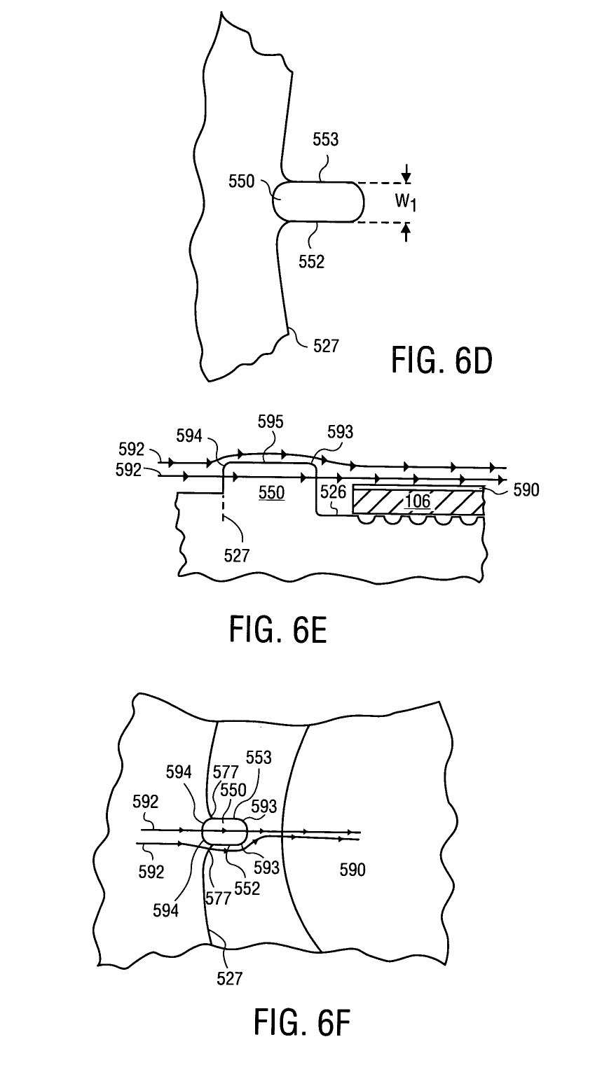

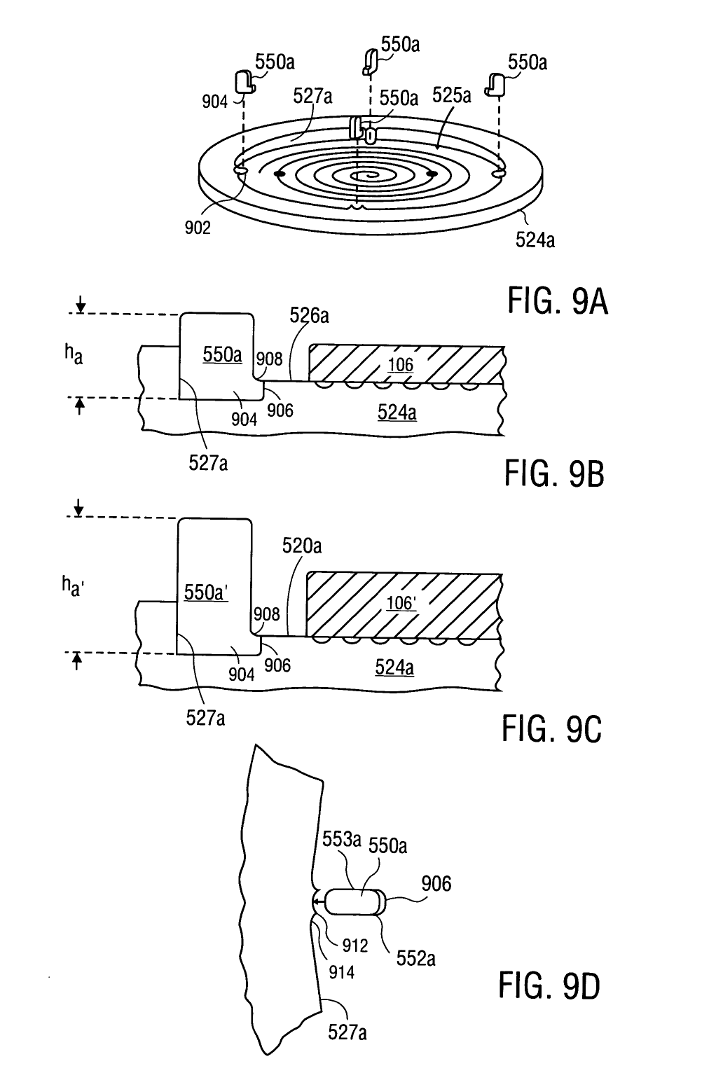

Wafers are placed into and removed from chamber 502 by the robotic wafer handling system 420 of FIG. 4 through the opening 414a formed in the sidewall of the chamber. A susceptor 524 holds the wafer in position during the semiconductor layer deposition process. As shown in FIG. 5, susceptor 524 includes a pocket 525 that is defined by at least one bottom surface 526 and a cylindrical sidewall 527. The depth of pocket 525 is approximately the same as the height of the cylindrical sidewall 527. Susceptor 524 may also include raised tabs 550 having a height that is independent of the depth of the pocket 525. Various embodiments of the susceptor 524 with raised tabs 550 are described herein in further detail below in conjunction with FIGS. 6A-6F and 9A-9D.

Still referring to FIG. 5, susceptor support 529 is coupled to susceptor 524 for rotating the wafer during the semiconductor fabrication process. Susceptor 524 also includes a plurality of through holes 540 for receiving at least three pins 542. Loading position pins 542 are attached to a support shaft 544 that provides vertical movement to raise and lower pins 542. Pins 542 are used to raise a wafer above the susceptor surface 526 while the wafer is being loaded or unloaded into the chamber. Raising of the wafer prevents scraping or other damage to the susceptor surface when the wafer is loaded or unloaded.

Heating lamps 528 provide infrared radiant heat into the chamber through window portion 514 and quartz lower member 516 which are transparent to infrared radiation. Temperature sensors 555, such as pyrometers, are utilized to measure the temperature of a wafer when it is being processed inside the chamber 406a.

FIGS. 6A-6F illustrate a semiconductor wafer susceptor 524 (“susceptor”) with raised tabs 550 (“tabs”) according to one embodiment of the invention. Referring to the three dimensional, perspective view of FIG. 6A, the susceptor 524 includes a wafer pocket 525 (“pocket”) that is defined by at least one grooved bottom surface 526 and a cylindrical sidewall 527. The height of the sidewall 527 defines the depth of the pocket (“pocket depth”), or in other words, the height of the sidewall is equal to the pocket depth. The susceptor 524 also may have a plurality of through holes 540 for receiving the pins 542 described above in conjunction with FIG. 5. The susceptor 524 may also include grooves 560 that have been formed into the bottom surface 526 of the susceptor 524. The grooves 560 are to contain air therein to prevent a vacuuming effect between the bottom surface of the wafer 106 and the bottom surface 526 of the susceptor 524. By preventing a vacuuming effect, the wafer 106 can be extracted more easily from the pocket 524 after wafer processing is completed. The susceptor 524 may be composed of graphite with a thin carbon coating.

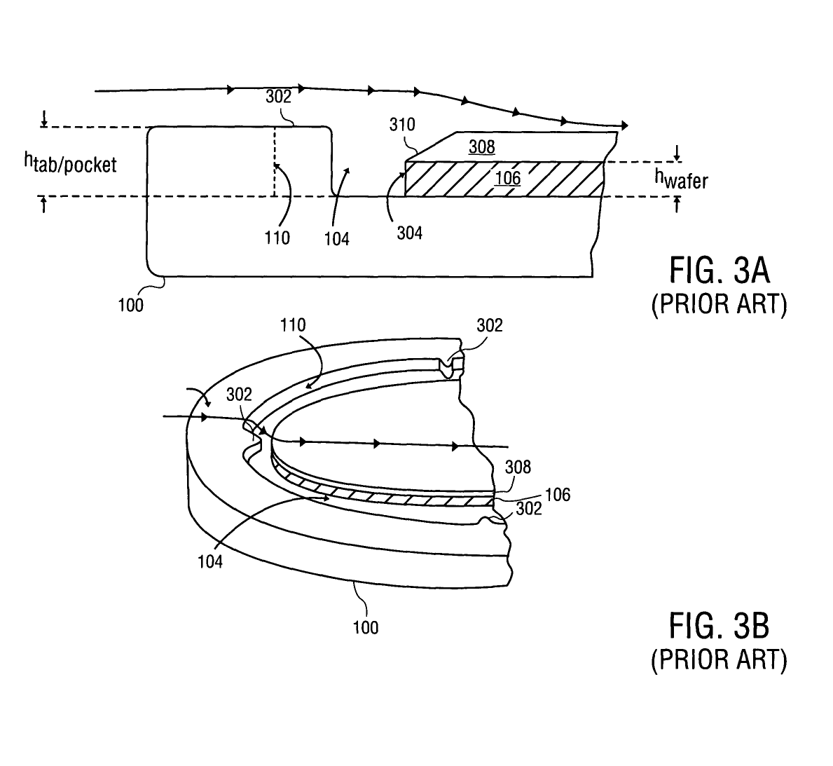

The susceptor 524 also includes a plurality of raised tabs 550 that are immovably affixed to the sidewall 527 along the outer perimeter of the wafer pocket 525 as shown in FIG. 6A. The tabs 550 are to contain the wafer inside the pocket 525 during wafer processing when the wafer 106 becomes stressed and agitated and, hence, attempts to leave the wafer pocket 525 as occurs in the “wafer-out-of-pocket” phenomenon. The tabs 550 have a height that is independent of the depth of the pocket. Herein, the phrase “independent of pocket depth” refers to the physical difference in tab height and pocket depth which difference ultimately affects the functions of both the tabs 550 and the sidewall 527. In other words, as shown in cross-sectional side-view FIG. 6B, it is advantageous for the tab height (h₁) to be different than the sidewall height (h₂) since the tab height (h₁) and the sidewall height (h₂) serve different functions during processing of the wafer 106. More specifically, as shown in FIG. 6B, the tabs 550 are shown to have a tab height (h₁) that is adapted to capture and contain the wafer 106 inside the pocket 525 during stressful processing conditions that would otherwise cause the wafer to leap above the sidewall 527 and out of the pocket 525. As shown in cross-sectional side-view FIG. 6C, during wafer processing (e.g., during temperature ramping) the wafer 106 will become subject to warping, or other stresses, that may cause the bottom surface 511 of the wafer to raise off of the bottom surface 526 of the susceptor 524 so that the bottom surface 511 of the wafer 106 would rise above the height of the sidewall 527 while at the same time, the warping and other stresses cause the wafer 106 to move laterally in a direction that, if not for the obstruction of the raised tabs 550, the wafer side edge 340 would move beyond the confines of the wafer pocket 525 resulting in wafer-out-of-pocket. The movement of the wafer 106, both horizontally and laterally, that would cause the wafer 106 to leave the pocket 525, may be termed, herein, the “wafer displacement”. However, the tab 550 has a tab height (h₁) that is adapted to compensate for the wafer displacement so that the tab front edge 551 will block the lateral movement of the wafer 106 by engaging the edge 304 of the wafer 106, as shown in FIG. 6C thus eliminating the problem of wafer-out-of pocket. After the wafer edge 340 and tab edge 351 collide, curvature 587 permits the wafer 106 to slide away from the tab 550. At the same time, referring back to FIG. 6B, the sidewall height (h₂) is significantly lower than the tab height (h₃) and approximately equal to the wafer height (h₃). Since the sidewall height (h₂) is approximately equal to the wafer height (h₃), a thin film can be formed more uniformly on the top surface of the wafer 106, thus preventing the formation of “thin edges” as defined in FIG. 3 above. Thus, the sidewall 527 and tabs 550 can perform their respective functions during wafer processing without interfering with each other.

As described above, the tab height (h₁) should be adapted to capture and contain the wafer 106 inside the pocket 525, or in other words, to confine the wafer 106 to the pocket 525. The quantitative height of the tab height (h₁) will depend on the characteristics of the wafer 106 (e.g., wafer mass, wafer height, etc.) and the wafer processing conditions (e.g., temperature of processing, rotation rate, etc.) that cause wafer displacement. In other words, different wafer characteristics and different processing conditions may affect the movement of the wafer in the pocket differently. For example, a 200 mm wafer, as understood in the art to be a circular wafer having a 200 mm diameter, has a height, weight, mass, etc., that is different from that of a 300 mm wafer or a 100 mm wafer. Additionally, a process that includes temperature ramping, that is, dramatic changes in temperature, may cause more stress in the wafer than other processes that don't utilize temperature ramping. Thus, for a 200 mm wafer, the quantitative value for a tab height may differ from the quantitative value for a tab height for a 300 mm wafer or a 100 mm wafer. Additionally, for a temperature-ramping deposition process, the quantitative value may differ from the quantitative value for a non-temperature ramping wafer processing procedure. Nevertheless, for exemplary purposes, in one embodiment of the invention, susceptor 524 may include a tab height (h₁) approximately equal to about 0.034 to about 0.04 inches, and a sidewall height of approximately 0.018 inches.

Referring back to FIG. 6B, the tabs 550 extend into the pocket 525 to maintain the wafer 106 separated from the sidewall 527. The tabs 550 may extend directly toward the center of the pocket 525 to a tab length (I₁) measured beginning at the sidewall 527 and terminating at the tab front edge 551. The tab length (I₁), therefore, should be adapted to maintain the wafer side edge 340 away from the sidewall 526 to prevent the sidewall 526 from having a significant thermal effect on the wafer side edge 340, or in other words, to prevent the wafer side edge 340 from being significantly influenced by the temperature (i.e. thermal mass) of the sidewall 527. Additionally, as shown in top-view FIG. 6D the tab 550 has a tab width (w₁) measured from tab side edge 552 to tab side edge 553. The advantage of a tab 550 that extends into the pocket 525 is that the tab 550 can keep the wafer 106 away from the thermal influence of the sidewall 527 during processing. The thermal influence of the sidewall 527 would lead to the formation of anomalies that would be detrimental to thin film uniformity. The tab width (w₁), therefore, should be configured so that the tab 550 has an insignificant thermal effect on the wafer side edge 340 if the wafer side edge 340 comes into contact with, and remains in thermal proximity to, the tab 550 during wafer processing. Quantitative values of the length (I₁) and width (w₁) will depend on the dimensions and material properties of the wafer 106 as well as the conditions of the wafer process being performed. However, for exemplary purposes, in one embodiment of the invention, the tab length (I₁) may be approximately 0.125 inches and the tab width may be approximately 0.063 inches.

FIG. 6E and FIG. 6F are cross-sectional side and top views, respectively, demonstrating the aerodynamic properties of the tabs 550 to a laminar gas flow 592. Referring to FIG. 6E, the tabs 550 are specially shaped to minimize interference with the laminar gas flow 592 over the wafer top surface during processing to form a thin film 590. More specifically, the tabs 550 have rounded corners and edges forming a general smooth shape with aerodynamic properties that do not substantially interfere with the flow of the gas. The smooth, aerodynamic shape of the tabs 550 contributes to the formation of a more uniform thin film 590. For example, as shown in FIG. 6E and 6F, front corners 593 and back corners 594 are smooth and rounded and transition smoothly into side edges 552 and 553 and tab top 595. Consequently, laminar gas flow 592 moves smoothly over corners 593, 594. Additionally, the sidewall 527 has a smooth curvature 577 where the tab 550 connects to the sidewall 527.

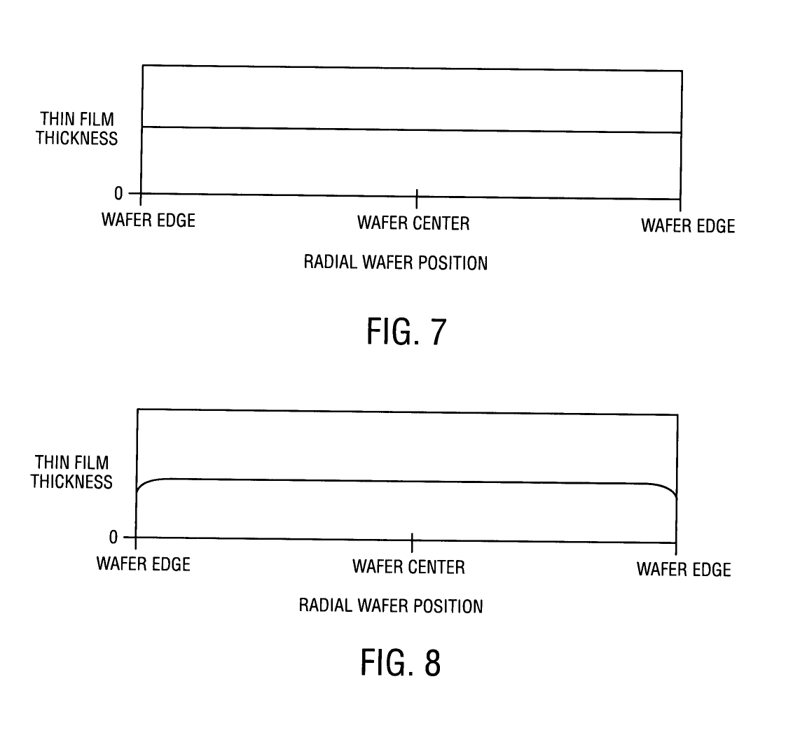

FIG. 7 is a graph of thickness uniformity for a thin film formed on the susceptor 524 with raised tabs 550 and a low sidewall 527. Referring to FIG. 7, the thin film formed with the raised tabs 550 allows for a lower susceptor sidewall 527, hence a lower pocket 525, thus forming a substantially uniform thin film thickness from wafer edge to wafer edge. Contrarily, if the tabs 550 of the susceptor 524 were not raised, or in other words, if the pocket depth were to be constrained to be as tall as the tab height, thin edges of the thin film would form at the wafer edges, as shown in FIG. 8 and as described in conjunction with FIG. 3 above.

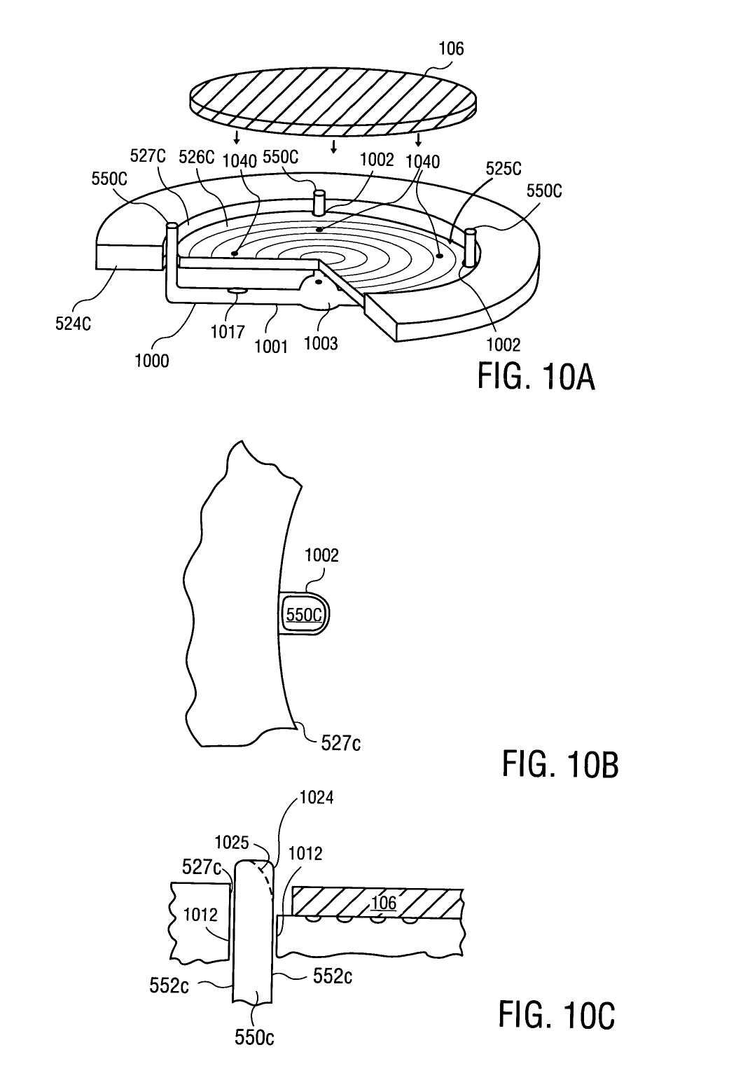

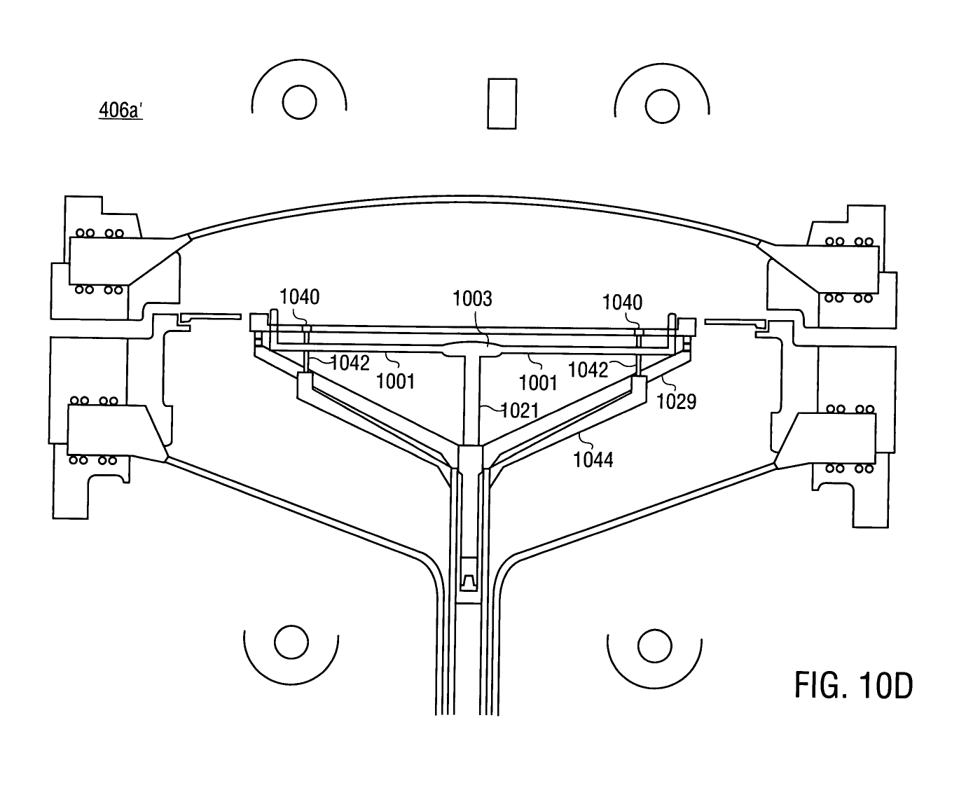

In the embodiments of the invention described in conjunction with FIGS. 6A-6F, the raised tabs 550 are described a being immovably affixed to the susceptor 524, hence the height of the tab (“tab height”) is fixed in a position that is taller than the depth of a susceptor pocket (“pocket depth”). However, other embodiments of the invention, as illustrated in FIGS. 9A-9D and FIGS. 10A-10D, may include a susceptor that has tabs that are not necessarily always in a fixed raised position, but that are adjustable, meaning that the tab is capable of movement with respect to the susceptor, or more specifically that the tab is vertically movable so that the tab height can be positioned in a different vertical orientation relative to the pocket depth. Hence, an adjustable tab can be placed into a raised position so that the tab height is adapted toconfine the wafer to the wafer pocket, but the tabs do not necessarily always have to remain in the raised position.

FIGS. 9A-9D illustrate a susceptor 524a having removable raised tabs 550a. Referring to the three-dimensional, perspective view of FIG. 9A, susceptor 524a may have mostly the same characteristics of susceptor 524 as described in conjunction with FIGS. 6A-6F above, but the tabs 550a are removable. Hence, the susceptor 524a would include indentations 902 that form fit to the bottom portion 904 of the tabs 550a. The indentations 902 should have a depth adapted to maintain the tabs 550a in a stable, upright position. Tabs 550a share the same general shape and function as tabs 550 described in conjunction with FIGS. 6A-6F above, including that the tabs 550a have a height adapted to confine the wafer 106 to the wafer pocket 525a when the wafer 106 is stressed. The height of the tabs 550a are independent of the height of the sidewall 527a, thus permitting the sidewall 527a to be low, which allows for the formation of uniform thin films. An additional advantage of susceptor 524a is that the tabs can be removed and replaced with tabs of differing heights. This allows for different sized wafers to be processed within the same susceptor 524a. For example, as shown in the cross-sectional side view of FIG. 9B, a wafer 106 may have a given size and possess characteristics that would cause the wafer 106 to become stressed and/or agitated to a certain degree so that the tab 550a would need to have a height (hₐ) adapted to contain the wafer 106 within the wafer pocket 525a. However, a larger wafer 106′, as shown in FIG. 9B, would be stressed and agitated to a degree that is different than the degree of stress and agitation that wafer 106 would experience during wafer processing. Thus, wafer 106′ may require a tab 550a′ that has a height (h_{a′}) different from the height (hₐ) required by wafer 106.

Referring still to FIGS. 9A-9D, tabs 550a also have smooth rounded corners and edges, just like tabs 550 described earlier. Tabs 550a may have portions that smoothly transition into the shape of the susceptor 524a. For example, tabs 550a may have a foot 906 with a curvature 908 that smoothly transitions into the bottom surface 526a of the susceptor. Additionally, the susceptor 524a may have portions that blend into the shape of the tabs 550a. For example, as shown in the top-view of FIG. 9D, the sidewall 527a may have a portion 912 with a curvature 914 that transitions smoothly into the tab side edge, 552a and 553a of the tab 550a.

FIGS. 10A-10D illustrate a susceptor 524c with a tab holder 1000 that holds tabs 550c to be lifted up through the susceptor 524c into a raised position from underneath the susceptor 524c. Referring to the three-dimensional, perspective view of FIG. 10A, susceptor 524c may have mostly the same characteristics of susceptor 524 as described in conjunction with FIGS. 6A-6F above, but the tabs 550c are retractable. The susceptor 524c includes a plurality of through holes 1002 that extend entirely through the bottom surface 526c of the susceptor 524c, each through hole 1002 having a shape that allows the respective tab 550c to pass through unobstructed. The through holes 1002 are positioned along the perimeter of the pocket 525c along the sidewall 527c of the pocket 525c. The shape of the through hole 1002 is similar to the outlined shape of the tab 550c, as shown in top view FIG. 10B and cross-sectional side view FIG. 10C, the through hole 1002 is formed so that the tab side edges 552c are nearly flush against (i.e., nearly touching) the inside edges 1012 of the through hole 1002. The pocket sidewall 527c is in vertical alignment with a portion of the inside edge 1012 of the through hole 1002 so that the tab 550c can also be nearly flush against the pocket sidewall 527c. The through hole 1002 begins at the pocket sidewall 527c and extends from the pocket sidewall 527c inward a short distance in the direction of the susceptor pocket so that when the tabs 550c are inserted through the through holes 1002, the tabs 550 will maintain the wafer 106 centered within the pocket and away from the thermal influence of the sidewall 527c. The front edge 1024 of the tab 550c may have a rounded shape to assist the wafer into the wafer pocket when the tabs 550c are in a raised position. In one embodiment of the invention, an edge 1025 of the tab 550c may instead be formed to have a steep downward slope in the direction of the wafer pocket to further assist the wafer 106 in sliding inward toward the wafer pocket when tabs 550 are in a raised position.

The configuration of the tab holder 1000 is shown in FIG. 10A as having arms 1001 extending radially from a centralized hub 1003. The tab holder 1000 is capable of being raised and lowered so that tabs 550c can be raised and lowered through the through holes 1002. The configuration of the tab holder 1000 should be compatible with the configuration of various elements of the processing chamber in which the susceptor 524c is used. For example, FIG. 10D shows a processing chamber 406a substantially similar to the processing chamber 406a described in conjunction with FIG. 5 above. Among other things, the processing chamber 406a includes a susceptor support 1029 for holding the susceptor 524c in place, loading position pins 1024 to assist in the insertion and removal of the wafer 106 from the susceptor 524c, and a support shaft 1044c attached to the loading position pins 1024c that provides vertical movement to raise and lower pins 1042 through the through holes 1040c in the susceptor 524c. Consequently, the configuration of the tab holder 1000 is compatible with the configuration of the susceptor support 1029, the support shaft 1044, and the loading pins 1042 in a way that does not interfere with the respective function of each. For instance, the susceptor 524c may be held by a tab holder support shaft 1021 that rotates in a manner consistent with the rotation of the support shaft 1044. Hence, from a compatibility standpoint, the susceptor holder 1000 may include pin through holes 1017 in each arm 1001 through which the pins 1024 may pass. Otherwise, the arms 1001 of the tab holder 1000 may simply be positioned offset from the pins 1042 and rotated in a relatively constant position as the support shaft 1044 during wafer processing so that the pins 1042 do not collide with the arms 1001 of the tab holder 1000. Other compatible configurations may be readily apparent to one ordinarily skilled in the art whereby the tab holder 1000 can be utilized in a manner that does not interfere with the various elements of the processing chamber underneath the susceptor 524c.

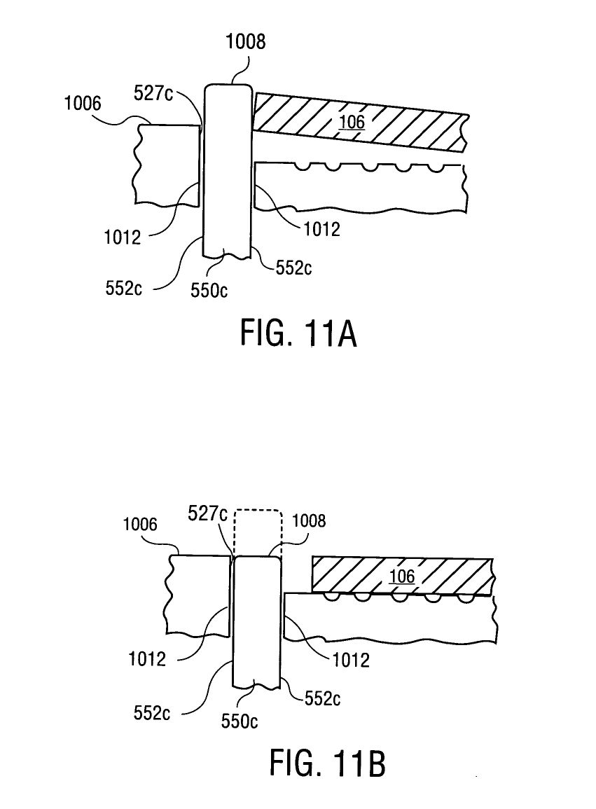

An advantage of utilizing the embodiment described in FIGS. 10A-10D is that the tabs 550c do not always need to be in a raised position during wafer processing. For instance, as shown in FIGS. 11A-11B, during operation, the tabs 550c may be raised to a height so that the tabs 550c confine the wafer 104c to the pocket 525c when the wafer 106 is stressed. For example, during temperature ramping, the wafer becomes especially stressed, therefore just before temperature ramping procedures, the tabs 550c would be moved upward into the raised position shown in the cross-sectional view of FIG. 11A, to contain the wafer 106 if the wafer 106 attempts to move beyond the confines of the pocket 525c. Once the stressful time is over for the wafer 106, however, it may be advantageous to lower the tabs 550c, as shown in the cross-sectional view of FIG. 11B, so that the top 1008 of the tab 550c is level with the top 1006 of the pocket sidewall 527. Therefore, during a time when the wafer is not significantly stressed and probably will not be as active as during temperature ramping, the tabs 550c can still function to center the wafer 106 in the pocket and prevent the wafer 106 from getting too close to the sidewall 527c. At least one advantage of lowing the tabs to the position shown in FIG. 11B is that the lowered tab 550c will have less aerodynamic drag effect on laminar gas flow during certain portions of wafer processing when the gas is flowing over the surface of the wafer 106.

Several embodiments of the invention have thus been described. However, those ordinarily skilled in the art will recognize that the invention is not limited to the embodiments described, but can be practiced with modification and alteration within the spirit and scope of the appended claims that follow.

1. An apparatus, comprising:
a wafer susceptor having a wafer pocket to contain a wafer, the wafer pocket having a pocket depth; and
a plurality of tabs to maintain the wafer in the wafer pocket, the tabs having a tab height that is independent of the pocket depth.

2. The apparatus of claim 1, wherein the wafer pocket includes a sidewall having a sidewall height defining the depth of the wafer pocket, and the plurality of tabs having a tab height greater than the sidewall height.

3. The apparatus of claim 1, wherein the plurality of tabs are affixed to a sidewall of the wafer pocket.

4. The apparatus of claim 1, wherein the plurality of tabs are vertically movable so that the tab height can be positioned in a different vertical orientation relative to the pocket depth.

5. The apparatus of claim 1, wherein the tabs have rounded corners and edges that will not substantially interfere with a laminar gas flow.

6. The apparatus of claim 1, wherein the wafer pocket includes a grooved bottom surface to prevent a vacuuming effect between the wafer and the susceptor.

7. The apparatus of claim 1, wherein the plurality of tabs extend into the wafer pocket and are configured to maintain the wafer centered in the pocket and to keep the wafer away from a thermal influence of the sidewall.

8. The apparatus of claim 1, wherein the pocket depth is about 0.018 inches and the tab height is about 0.034 to about 0.04 inches.

9. The apparatus of claim 1, wherein the plurality of tabs extend into, and directly toward, the center of the pocket and have a length of about 0.125 inches and a width of about 0.063 inches.

10. The apparatus of claim 1, wherein the plurality of tabs extend into the wafer pocket and are configured to maintain the wafer centered in the pocket and to keep the wafer away from a thermal influence of the sidewall.

11. The apparatus of claim 1, wherein the plurality of tabs are removable and wherein the susceptor includes a plurality of indentations that form fit to individual bottom portions of the plurality of tabs to maintain the tabs in a stable, upright position.

12. An apparatus, comprising:
a wafer susceptor having a wafer pocket to contain a wafer, the wafer pocket defined by a bottom surface and a cylindrical sidewall, the wafer pocket having a depth that is defined by the height of the cylindrical sidewall, the grooved bottom surface having a plurality of through holes therein that extend entirely through the susceptor, the through holes positioned adjacent to the cylindrical sidewall; and
a tab holder having a plurality of tabs, each of the plurality of tabs having a tab height that is independent of the pocket depth, the plurality of tabs to be inserted into the plurality of through holes from below the susceptor and raised to a height adapted to maintain the wafer confined to the pocket during wafer processing.

13. The apparatus of claim 12, wherein the shape of each individual through hole allows each individual tab to pass through unobstructed.

14. The apparatus of claim 12, wherein the tab holder includes arms extending radially from a centralized hub.

15. The apparatus of claim 12, wherein the tab holder is capable of being raised and lowered so that the plurality of tabs can be raised and lowered through the through holes.

16. The apparatus of claim 12, further comprising a rotatable susceptor holder to support and rotate the susceptor, and wherein the configuration of the tab holder is compatible with the configuration of the rotatable susceptor holder in a way that does not interfere with the rotatable susceptor holder during wafer processing.

17. A method, comprising:
placing a wafer inside a wafer pocket of a susceptor, the wafer pocket defined by a cylindrical sidewall and a bottom surface.
positioning a plurality of tabs into a raised position above the wafer pocket, the raised tabs having a height adapted to contain the wafer inside the wafer pocket when the wafer attempts to leave the wafer pocket; and
performing a wafer processing procedure.

18. The method of claim 17, wherein the susceptor includes a plurality of through holes therein that extend entirely through the bottom surface of the wafer pocket, the plurality of through holes positioned along the perimeter of the wafer pocket along the cylindrical sidewall, and the method further comprising:
raising the plurality of tabs through the plurality of through holes until the plurality of tabs are raised to the adapted height.

19. The method of claim 18, including raising the plurality of tabs before a processing techniques is performed that will cause the wafer to become stressed to a degree that a portion of the wafer raises above the cylindrical sidewall and attempts to leave the wafer pocket.

20. The method of claim 18, further comprising:
lowering the plurality of tabs during processing techniques that do not stress the wafer to a degree that would cause the wafer to leave the wafer pocket.

21. The method of claim 17, wherein the susceptor includes a plurality of indentations, and wherein the plurality of tabs are removable tabs each having a bottom portion that form fits to the indentations, and the method further comprising:
placing the plurality of removable tabs into the indentations.
